(19) United States
(12) Patent Application Publication
(10) Pub. No.: US 2012/0043121 A1
(43) Pub. Date: Feb. 23, 2012

(54) PRINTED CIRCUIT BOARD AND METHOD OF MANUFACTURING THE SAME

(75) Inventor: Jong Seok Bae, Gyunggi-do (KR)

(73) Assignee: SAMSUNG ELECTRO-MECHANICS CO., LTD., Gyunggi-do (KR)

(21) Appl. No.: 13/211,795

(22) Filed: Aug. 17, 2011

(30) Foreign Application Priority Data
Aug. 18, 2010 (KR) 1020100079982

(51) Int. Cl. H05K 1/09; H05K 1/00; H01B 13/00; H05K 1/11; C25D 5/02; C25D 7/00

(52) U.S. Cl. 174/257; 205/125; 216/20; 174/262; 174/258

(57) ABSTRACT

Disclosed herein are a printed circuit board and a method of manufacturing the same. The printed circuit board includes: an insulating layer; a first circuit layer including a first metal layer and a first plating layer provided on an outer side of the first metal layer and embedded in one surface of the insulating layer; a second circuit layer including a second metal layer and a second plating layer provided on an outer side of the second metal layer and embedded in the other surface of the insulating layer; and a bump interconnecting the first circuit layer and the second circuit layer while penetrating through the insulating layer. The bump is used, such that there is no need to perform hole plating. Therefore, an increase in the surface plating thickness due to the hole plating is previously prevented.

### CROSS REFERENCE TO RELATED APPLICATION

This application claims the benefit of Korean Patent Application No. 10-2010-0079982, filed on Aug. 18, 2010, entitled “Printed Circuit Board And Method Of Manufacturing The Same”, which is hereby incorporated by reference in its entirety into this application.

### BACKGROUND OF THE INVENTION

1. Technical Field

The present invention relates to a printed circuit board and a method of manufacturing the same.

2. Description of the Related Art

A printed circuit board is generally formed by forming wiring on one surface of both surfaces of a board made of various thermosetting synthetic resins using a copper foil, fixedly disposing integrated circuits (ICs) or electronic components on the board, implementing electrical wiring between the ICs or the electronic components, then coating the electrical wiring using an insulator.

In accordance with the recent development in the electronic industry, the demand for multi-functional and slim and light electronic components has rapidly increased. Therefore, a printed circuit board having the electronic components mounted thereon has also been demanded to have a high density wiring and a thin thickness.

However, in the case of a process of manufacturing a printed circuit board according to the prior art, the printed circuit board is manufactured by forming a through hole in a copper clad laminate (CCL) and then performing a circuit layer forming process. Here, hole plating is performed on an inner wall of the through hole in order to interconnect circuit layers. However, a surface plating thickness at the time of forming the circuit layer is increased due to the hole plating, such that the circuit layer may not be finely formed. In addition, a thickness of the entire printed circuit board is increased due to the increase in the surface plating thickness, such that the printed circuit board having a thin thickness may not be implemented.

### SUMMARY OF THE INVENTION

The present invention has been made in an effort to provide a printed circuit board in which a bump is used to reduce a surface plating thickness at the time of forming circuit layers, thereby finely forming the circuit layers and implementing the printed circuit board having a thin thickness, and a method of manufacturing the same.

According to a first preferred embodiment of the present invention, there is provided a printed circuit board including: an insulating layer; a first circuit layer including a first metal layer and a first plating layer provided on an outer side of the first metal layer and embedded in one surface of the insulating layer; a second circuit layer including a second metal layer and a second plating layer provided on an outer side of the second metal layer and embedded in the other surface of the insulating layer; and a bump interconnecting the first circuit layer and the second circuit layer while penetrating through the insulating layer.

The printed circuit board may further include solder resist layers formed on both surfaces of the insulating layer so as to have openings exposing a pad part of the first circuit layer and a pad part of the second circuit layer.

The first metal layer or the second metal layer may be made of copper, nickel, or aluminum.

The insulating layer may be formed of a prepreg or an Ajinomoto build up film (ABF).

According to a second preferred embodiment of the present invention, there is provided a method of manufacturing a printed circuit board, the method including: (A) printing bumps on one surface of a first metal layer supported by a first metal support layer; (B) stacking an insulating layer on one surface of the first metal layer so as to have the bumps penetrating therethrough; (C) stacking a second metal layer supported by a second metal support layer on one surface of the insulating layer so as to contact the bumps and then removing the first and second metal support layers; and (D) selectively plating the first and second metal layers to form each of first and second plating layers, thereby forming first and second circuit layers.

At the stacking of the insulating layer includes, an upper portion of the bump penetrating through the insulating layer may be exposed, and at the stacking of the second metal layer, the second metal layer may contact the upper portion of the bump.

The forming of the first and second circuit layers may include: (D1) applying plating resists to each of the first and second metal layers; (D2) patterning openings for forming circuits in the plating resist through an exposure process and a develop process; (D3) selectively plating the opening for forming circuits through a plating process to thereby form the first and second plating layers; and (D4) removing the plating resists.

The forming of the first and second circuit layers may further include removing the exposed first and second metal layers through an etching process, after the removing of the plating resists.

The method may further include compressing the first and second circuit layers to thereby embed them in the insulating layer, after the forming of the first and second circuit layers.

The method may further include forming solder resist layers on both surfaces of the insulating layer so as to have openings exposing a pad part of the first circuit layer and a pad part of the second circuit layer, after the forming of the first and second circuit layers.

At the stacking of the second metal layer, the insulating layer may be in a B-stage stage.

The first metal support layer may have a thickness thicker than that of the first metal layer, and the second metal support layer may have a thickness thicker than that of the second metal layer.

The first metal layer or the second metal layer may be made of copper, nickel, or aluminum.

The insulating layer may be formed of a prepreg or an Ajinomoto build up film (ABF).

### BRIEF DESCRIPTION OF THE DRAWINGS

FIG. 1 is a cross-sectional view of a printed circuit board according to a preferred embodiment of the present invention; and

FIGS. 2 to 13 are cross-sectional views showing a method of manufacturing a printed circuit board according to a preferred embodiment of the present invention in a process sequence.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The objects, specific advantages, new features of the present invention will be more clearly understood from the following detailed description taken in conjunction with the accompanying drawings. In the specification, in adding reference numerals to components throughout the drawings, it is to be noted that like reference numerals designate like components even though components are shown in different drawings. In the description, the terms “first”, “second”, and so on are used to distinguish one element from another element, and the elements are not defined by the above terms. Further, in describing the present invention, a detailed description of related known functions or configurations will be omitted so as not to obscure the subject of the present invention.

Hereinafter, preferred embodiments of the present invention will be described in detail with reference to the accompanying drawings.

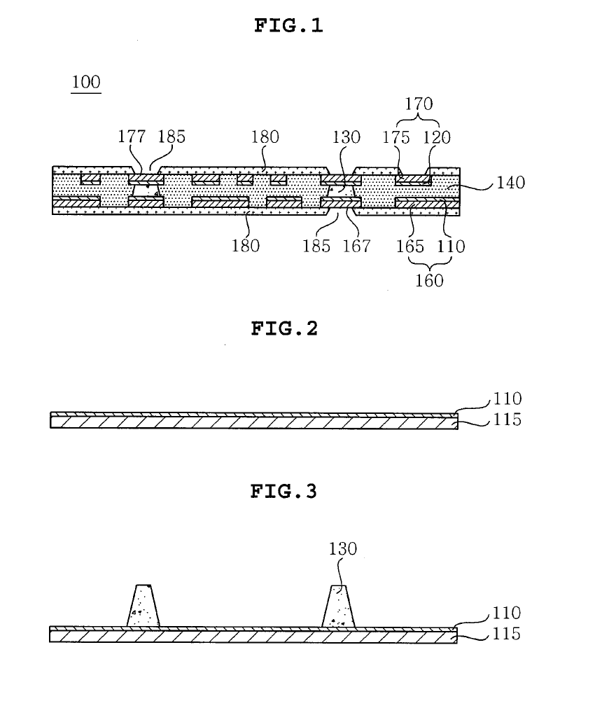

FIG. 1 is a cross-sectional view of a printed circuit board according to a preferred embodiment of the present invention.

As shown in FIG. 1, a printed circuit board 100 according to the present embodiment is configured to include an insulating layer 140, a first circuit layer 160 including a first metal layer 110 and a first plating layer 165 provided on an outer side of the first metal layer 110 and embedded in one surface of the insulating layer 140, a second circuit layer 170 including a second metal layer 120 and a second plating layer 175 provided on an outer side of the second metal layer 120 and embedded in the other surface of the insulating layer 140, and a bump 130 interconnecting the first circuit layer 160 and the second circuit layer 170 while penetrating through the insulating layer 140.

The insulating layer 140 serves to insulate the first circuit layer 160 and the second circuit layer 170 from each other. Here, a material of the insulating layer 140 is not specifically limited. However, as the material of the insulating layer 140, a prepreg having excellent adhesive force with the circuit layers 160 and 170 or an Ajinomoto build up film (ABF) capable of finely forming the circuit layers 160 and 170 is preferably used.

The first and second circuit layers 160 and 170 are embedded in both surfaces of the insulating layer 140. The first circuit layer 160 includes the first metal layer 110 and the first plating layer 165, and the second circuit layer 170 includes the second metal layer 120 and the second plating layer 175. Here, the metal layers 110 and 120 serve as a seed layer in a process of forming the circuit layers 160 and 170, and the plating layers 165 and 175 are formed through an electroplating process using the metal layers 110 and 120 as the seed layer. Therefore, the plating layers 165 and 175 are formed on outer sides of the metal layers 110 and 120 based on the insulating layer 140. Meanwhile, the metal layers 110 and 120 has electrical conductivity in order to serve as the seed layer, and are preferably made of copper, nickel, or aluminum having a relatively low coefficient of thermal expansion. However, a material of the metal layers 110 and 120 is not necessarily limited thereto.

In addition, the first and second circuit layers 160 and 170 are compressed to thereby be embedded in the insulating layer 140. Therefore, exposed surfaces of the first and second circuit layers 160 and 170 are disposed on the same plane as the insulating layer 140 unlike the prior art, such that the entire thickness of the printed circuit board 100 is reduced, thereby making it possible to implement the printed circuit board 100 having a thin thickness.

The bump 130, which serves to electrically interconnect the first and second circuit layers 160 and 170 formed on both surfaces of the insulating layer 140, is formed by printing a conductive paste using a screen printing scheme. Here, any conductive material may be used as the conductive paste composing the bump 130. For example, Ag, Pd, Pt, or a combination thereof may be used. In the printed circuit board 100 according to the present embodiment, the first and second circuit layers 160 and 170 are electrically interconnected using the bump 130. Therefore, there is no need to perform hole plating, such that an increase in a surface plating thickness due to the hole plating is previously prevented, thereby making it possible to finely form the circuit layers 160 and 170 and implement the printed circuit board having a thin thickness, as compared to the printed circuit board according to the prior art.

Meanwhile, solder resist layers 180 protecting the first and second circuit layers 160 and 170 may be formed on both surfaces of the insulating layer 140 so that a solder is not applied thereto at the time of soldering. Holes 185 are formed in the solder resist layers 180 so that a pad part 167 of the first circuit layer 160 and a pad part 177 of the second circuit layer 170 may be electrically connected to external circuits, thereby making it possible to expose the pad parts 167 and 177. Here, the hole 185 may be formed by using a YGA laser beam, a CO₂ laser beam, a photolithography process, or the like. In addition, a solder ball may be seated in the hole 185 as needed.

FIGS. 2 to 13 are cross-sectional views showing a method of manufacturing a printed circuit board according to a preferred embodiment of the present invention in a process sequence.

As shown in FIGS. 2 to 13, a method of manufacturing a printed circuit board 100 according to the present embodiment includes (A) printing bumps 130 on one surface of a first metal layer 110 supported by a first metal support layer 115, (B) stacking an insulating layer 140 on one surface of the first metal layer 110 so as to have the bumps 130 penetrating therethrough, (C) stacking a second metal layer 120 supported by a second metal support layer 125 on one surface of the insulating layer 140 so as to contact the bumps 130 and then removing the first and second metal support layers 115 and 125, and (D) selectively plating the first and second metal layers 110 and 120 to form each of first and second plating layers 165 and 175, thereby forming first and second circuit layers 160 and 170.

First, the first metal layer 110 supported by the first metal support layer 115 is prepared, as shown in FIG. 2. Here, the first metal support layer 115 supports the first metal layer 110, thereby making it possible to prevent the first metal layer 110 from being bent during a process of manufacturing the printed circuit board. In this case, the first metal support layer 115 preferably has a thickness thicker than that of the first metal layer 110 in order to secure support force of a predetermined strength or more. In addition, since the first metal layer 110 serves as a seed layer during an electroplating process, it is preferably made of copper, nickel, aluminum, or the like. Meanwhile, the first metal layer 110 and the first metal support layer 115 are bonded to each other using an adhesive film (not shown), or the like, such that the first metal support layer 115 may be easily removed in an operation to be described below.

Then, the bumps 130 are printed on one surface of the first metal layer 110, as shown in FIG. 3. Here, the bumps 130 may be printed by a screen printing scheme. The screen printing scheme indicates a scheme of performing printing by pushing a conductive paste using a squeeze device to thereby pass the conductive paste through an opening of a mask. That is, an opening position of the mask is arranged, and the conductive paste is applied to an upper surface of the mask. Then, when the conductive paste is pushed using the squeeze device, or the like, it is transferred while being extruded through the opening, such that it is printed to have a desired shape and height. Here, as the conductive paste, Ag, Pd, Pt, or a combination thereof is preferably used.

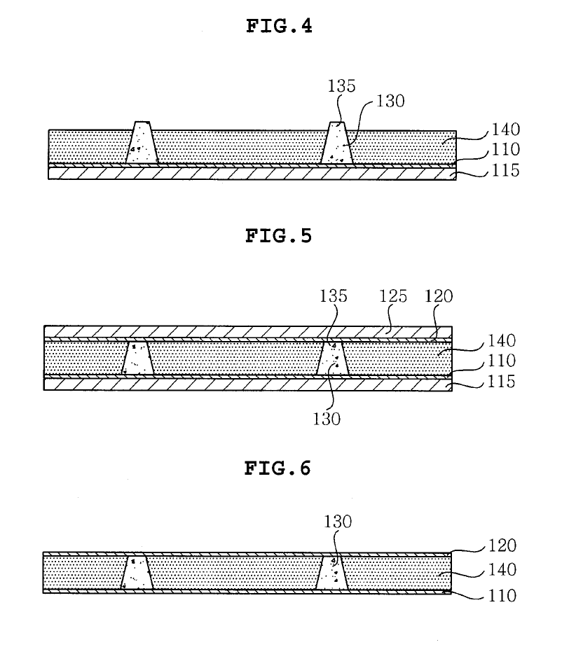

Next, the insulating layer 140 is stacked on one surface of the first metal layer 110 to have the bumps 130 penetrating therethrough, as shown in FIG. 4. Here, the insulating layer 140 is stacked in a B-stage state, and preferably has a thickness thinner than that of the bump 130 so that the bump 130 may penetrate therethrough and an upper portion 135 of the bump 130 may be exposed. The upper portion 135 of the bump 130 is exposed, such that the bump 130 may contact the second metal layer 120 when the second metal layer 120 is stacked in the next operation. Meanwhile, as a material of the insulating layer 140, a prepreg or an Ajinomoto build up film (ABF) may be used; however, a material of the insulating layer 140 is not necessarily limited thereto.

Thereafter, the second metal layer 120 supported by the second metal support layer 125 is stacked on one surface of the insulating layer 140, as shown in FIG. 5. Here, when the second metal layer 120 is stacked on one surface of the insulating layer 140, it contacts the upper portion 135 of the bump 130 penetrating through the insulating layer 140. In addition, the insulating layer 140 is maintained in the B-stage state up to this operation, such that the second metal layer 120 may be compressed and stacked on the insulating layer 140 at a temperature of 130 to 160° C., which is a relatively low temperature. Meanwhile, the second metal support layer 125 and the second metal layer 120 will be described in detail. Since the second metal support layer 125 serves to support the second metal layer 120, similar to the first metal support layer 115, it preferably has a thickness thicker than that of the second metal layer 120. In addition, since the second metal layer 120 serves as a seed layer during an electroplating process, similar to the first metal layer 110, it is preferably made of copper, nickel, aluminum, or the like. In addition, the second metal layer 120 and the second metal support layer 125 are bonded to each other using an adhesive film (not shown), or the like, such that the second metal support layer 125 may be easily removed in the next operation to be described below.

Then, the first metal support layer 115 and the second metal support layer 125 are removed, as shown in FIG. 6. Since the first and second metal layers 110 and 120 are bonded to the insulating layer 140, such that there is no risk that they will not be bent any more, the first and second metal support layers 115 and 125 are removed. As described above, since each of the first and second metal support layers 115 and 125 is bonded to each of the first and second metal layers 110 and 120 using an adhesive film, or the like, the first and second metal support layers 115 and 125 may be easily removed through a physical release process.

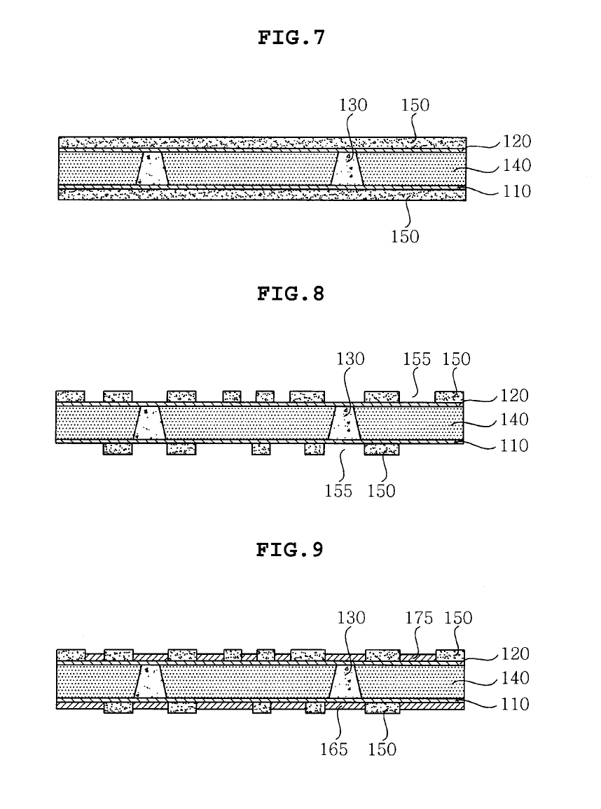

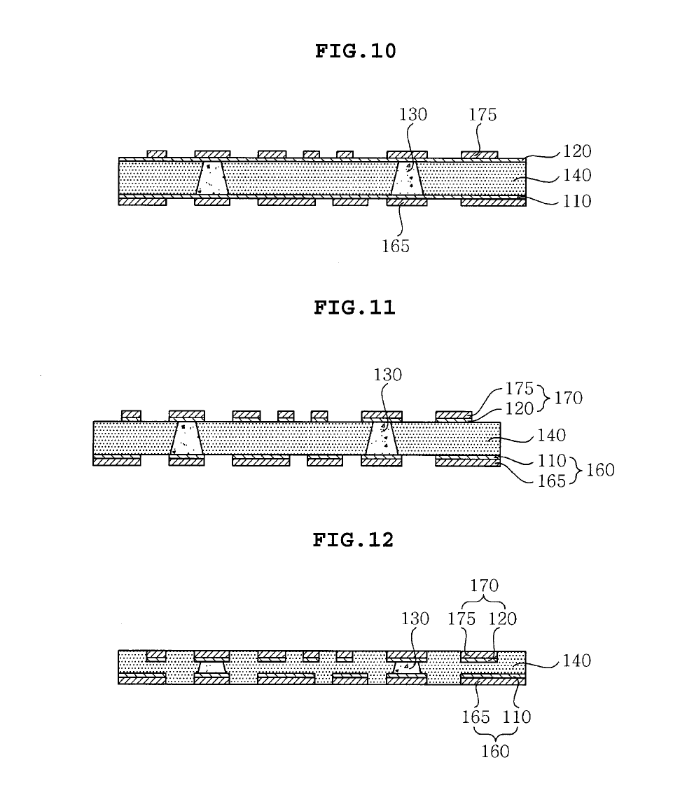

Next, the first circuit layer 160 and the second circuit layer 170 are formed, as shown in FIGS. 7 to 11. In order to form the first and second circuit layers 160 and 170, plating resists 150 are first applied to each of the first and second metal layers 110 and 120 (See FIG. 7). Here, as the plating resist 150, a dry film or a liquid state photosensitive material may be used. Then, openings 155 for forming circuits are patterned in the plating resist 150 through an exposure process and a develop process (See FIG. 8). Thereafter, an electroplating process is performed using the first and second metal layers 110 and 120 as a seed layer to selectively plate the openings 155 for forming circuits, thereby forming the first plating layer 165 and the second plating layer 175 (See FIG. 9). When the electroplating process ends, since the plating resist 150 is not required, it is removed (See FIG. 10). In addition, the first and second metal layers 110 and 120 exposed due to the removal of the plating resist 150 are removed through an etching process (for example, a flash etching process) (See FIG. 11). The circuit layers 160 and 170 including the metal layers 110 and 120 and the plating layers 165 and 175 are completed through the above-mentioned process.

The operation of forming the first and second circuit layers 160 and 170 is basically similar to a semi-additive process (SAP). However, in this operation, the first and second metal layers 110 and 120 are used as a seed layer, such that there is no need to perform an electroless plating process separately, thereby making it possible to simplify a process of manufacturing the printed circuit board.

Next, the first and second circuit layers 160 and 170 are compressed to thereby be embedded in the insulating layer 140, as shown in FIG. 12. Here, the first and second circuit layers 160 and 170 are compressed at a temperature of 200 to 250° C. by a press process, or the like, to thereby be embedded in the insulating layer 140. The first and second circuit layers 160 and 170 are embedded in the insulating layer 140, thereby making it possible to reduce the entire thickness of the printed circuit board 100.

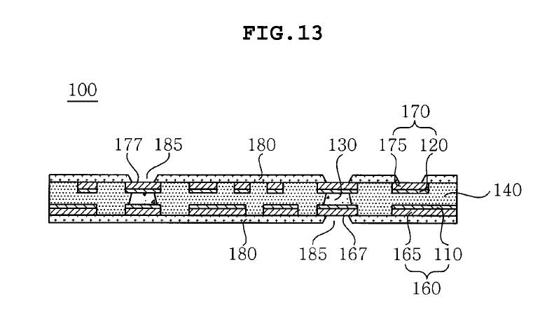

Then, the solder resist layers 180 are formed on both surfaces of the insulating layer 140, as shown in FIG. 13. Here, the solder resist layer 180 serves to protect the first and second circuit layers 160 and 170. Holes 185 are formed in the solder resist layers 180 so that the pad part 167 of the first circuit layer 160 and the pad part 177 of the second circuit layer 170 may be electrically connected to the external circuits, thereby making it possible to expose the pad parts 167 and 177.

As described above, according to the present invention, the bump is used, such that there is no need to perform hole plating. Therefore, an increase in the surface plating thickness due to the hole plating is previously prevented, thereby making it possible to finely form the circuit layers and implement the printed circuit board having a thin thickness.

In addition, according to the present invention, the circuit layers may be formed by performing an electroplating process using metal layers stacked on both surfaces of an insulating layer as a seed layer. Therefore, there is no need to perform an electroless plating process separately, thereby making it possible to simplify a process of manufacturing the printed circuit board.

Further, according to the present invention, the circuit layers are embedded in the insulating layer to reduce the entire thickness of the printed circuit board, thereby making it possible to implement the printed circuit board having a thin thickness.

Although the preferred embodiments of the present invention have been disclosed for illustrative purposes, they are for specifically explaining the present invention and thus a printed circuit board and a method of manufacturing the same according to the present invention is not limited thereto, but those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A printed circuit board comprising:
an insulating layer;
a first circuit layer including a first metal layer and a first plating layer provided on an outer side of the first metal layer and embedded in one surface of the insulating layer;
a second circuit layer including a second metal layer and a second plating layer provided on an outer side of the second metal layer and embedded in the other surface of the insulating layer; and
a bump interconnecting the first circuit layer and the second circuit layer while penetrating through the insulating layer.

2. The printed circuit board as set forth in claim 1, further comprising solder resist layers formed on both surfaces of the insulating layer so as to have openings exposing a pad part of the first circuit layer and a pad part of the second circuit layer.

3. The printed circuit board as set forth in claim 1, wherein the first metal layer or second metal layer is made of copper, nickel, or aluminum.

4. The printed circuit board as set forth in claim 1, wherein the insulating layer is formed of a prepreg or an Ajinomoto build up film (ABF).

5. A method of manufacturing a printed circuit board, the method comprising:
printing bumps on one surface of a first metal layer supported by a first metal support layer;
stacking an insulating layer on one surface of the first metal layer so as to have the bumps penetrating therethrough;
stacking a second metal layer supported by a second metal support layer on one surface of the insulating layer so as to contact the bumps and then removing the first and second metal support layers; and
selectively plating the first and second metal layers to form each of first and second plating layers, thereby forming first and second circuit layers.

6. The method as set forth in claim 5, wherein at the stacking of the insulating layer includes, an upper portion of the bump penetrating through the insulating layer is exposed, and
at the stacking of the second metal layer, the second metal layer contacts the upper portion of the bump.

7. The method as set forth in claim 5, wherein the forming of the first and second circuit layers includes:
applying plating resists to each of the first and second metal layers;
patterning openings for forming circuits in the plating resist through an exposure process and a develop process;
selectively plating the opening for forming circuits through a plating process to thereby form the first and second plating layers; and
removing the plating resists.

8. The method as set forth in claim 7, wherein the forming of the first and second circuit layers further includes removing the exposed first and second metal layers through an etching process, after the removing of the plating resists.

9. The method as set forth in claim 5, further comprising compressing the first and second circuit layers to thereby embed them in the insulating layer, after the forming of the first and second circuit layers.

10. The method as set forth in claim 5, further comprising forming solder resist layers on both surfaces of the insulating layer so as to have openings exposing a pad part of the first circuit layer and a pad part of the second circuit layer, after the forming of the first and second circuit layers.

11. The method as set forth in claim 5, wherein at the stacking of the second metal layer, the insulating layer is in a B-stage stage.

12. The method as set forth in claim 5, wherein the first metal support layer has a thickness thicker than that of the first metal layer, and
the second metal support layer has a thickness thicker than that of the second metal layer.

13. The method as set forth in claim 5, wherein the first metal layer or the second metal layer is made of copper, nickel, or aluminum.

14. The method as set forth in claim 5, wherein the insulating layer is formed of a prepreg or an Ajinomoto build up film (ABF).
